(19) United States
(12) Patent Application Publication
(10) Pub. No.: US 2026/0114305 A1
(43) Pub. Date: Apr. 23, 2026

(54) NOVEL MICRO BUMP STRUCTURE FOR INTERCONNECTION DIE

(71) Applicant: Taiwan Semiconductor Manufacturing Company, Ltd., Hsinchu (TW)

(72) Inventors: Jui-Shen CHANG, Taichung City (TW); Chun-Yung HUANG, Changhua County (TW); Chia-Lun CHANG, Kaohsiung City (TW); Chen-Nan CHIU, Hsinchu City (TW); Chang-Jung HSUEH, Taipei (TW)

(73) Assignee: Taiwan Semiconductor Manufacturing Company, Ltd., Hsinchu (TW)

(21) Appl. No.: 18/922,810

(22) Filed: Oct. 22, 2024

(51) Int. Cl. H01L 23/538; H01L 23/00; H01L 23/31; H01L 25/16; H10B 80/00

(52) U.S. Cl. CPC H10W 70/65; H10W 70/611; H10W 70/685; H10W 90/00; H10B 80/00; H10W 72/221; H10W 72/225; H10W 72/234; H10W 72/252; H10W 72/29; H10W 72/921; H10W 72/934; H10W 72/952; H10W 74/141; H10W 74/15; H10W 90/401; H10W 90/728; H10W 90/738

(57) ABSTRACT

A semiconductor device and a method of forming the same are provided. The semiconductor device includes an integrated circuit die, a dielectric layer, an under-bump metallurgy layer, an interconnection die, and a solder material. The integrated circuit die includes a first die connector. The dielectric layer is located on the integrated circuit die. The under-bump metallurgy layer has a line portion on the dielectric layer and a via portion extending through the dielectric layer to contact the first die connector. The interconnection die includes a second die connector. The solder material is located between the line portion of the under-bump metallurgy layer and the second die connector. The under-bump metallurgy layer includes a first copper layer having a uniform grain orientation, wherein the top surface of the first copper layer is in direct contact with the solder material.

### BACKGROUND

The semiconductor industry has experienced rapid grown due to continuous improvements in the integration density of a variety of electronic components (e.g., transistors, diodes, resistors, capacitors, etc.). For the most part, these improvements in integration density have come from successive reductions in minimum feature size, which allows more components to be integrated into a given area. As the demand for shrinking electronic devices has grown, a need for smaller and more creative packaging techniques of semiconductor dies has emerged.

Integrated Fan-Out (InFO) package technology is becoming increasingly popular, particularly when combined with Wafer-Level Packaging (WLP) technology in which integrated circuits are packaged in packages that typically include a redistribution layer (RDL) or post passivation interconnect that is used to fan-out wiring for contact pads of the package, so that electrical contacts can be made on a larger pitch than contact pads of the integrated circuit. The resulting package structures provide for a high functional density at a relatively low cost, and high-performance packages.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit (IC) die, in accordance with some embodiments.

FIGS. 2 to 9 are cross-sectional views of intermediate stages in the formation of an integrated circuit package, in accordance with some embodiments.

FIGS. 10 to 12 are various views of the die connector 144 and the under-bump metallurgy layer (UBML) 114B, in accordance with some embodiments.

FIG. 13 is an enlarged view of region C in FIG. 9, showing some micro bump structures between the interconnection die and the IC die, in accordance with some embodiments.

FIG. 14 is a cross-sectional view of an integrated circuit device, in accordance with some embodiments.

FIG. 15 illustrates some micro bump structures between the interconnection die and the IC die, in accordance with some embodiments.

FIG. 16 illustrates some micro bump structures between the interconnection die and the IC die, in accordance with some embodiments.

FIGS. 17A and 17B illustrate some micro bump structures between the interconnection die and the IC die, in accordance with some embodiments.

FIG. 18 illustrates some micro bump structures between the interconnection die and the IC die, in accordance with some embodiments.

FIG. 19 illustrates some micro bump structures between the interconnection die and the IC die, in accordance with some embodiments.

FIG. 20 illustrates that the die connectors of the IC die have the same material as the overlying UBML and the die connectors of the interconnection die, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In Integrated Fan-Out (InFO) packages, micro bump structures may be configured to allow interconnects to be formed between an interconnection die (e.g., a local silicon interconnect (LSI) die or the like) and one or more integrated circuit (IC) dies to which it is attached. Each micro bump structure typically includes a die connector (e.g., a metal pillar) of the interconnection die, an under-bump metallurgy layer (UBML) that is overlying and coupled to an IC die, and a conductive connector (e.g., a solder material) therebetween. During reflow, molten solder material tends to extend to the sidewalls of the die connector of the interconnection die and/or the UBML above the IC die (i.e., so-called solder sidewall wetting phenomenon), resulting in solder joint necking after the reflow process. This makes the micro bump structure weakened at this necking location and prone to cracking.

According to various embodiments, novel micro bump structures for interconnection dies are provided. In some embodiments, by adopting a metal layer containing grains oriented in a particular direction, for example, copper layer with a uniform grain orientation (e.g., <111> orientation) for the die connector of the interconnection die and the UBML above the IC die, the top surfaces of the die connector and the UBML are more easily wetted by molten solder material than their corresponding sidewalls. This allows molten solder material to be confined (e.g., retained) on and between the top surfaces of the die connector and the UBML without solder sidewall wetting occurring. Therefore, the structural strength and reliability of the micro bump structures are improved. Other advantages will be described below.

The Embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

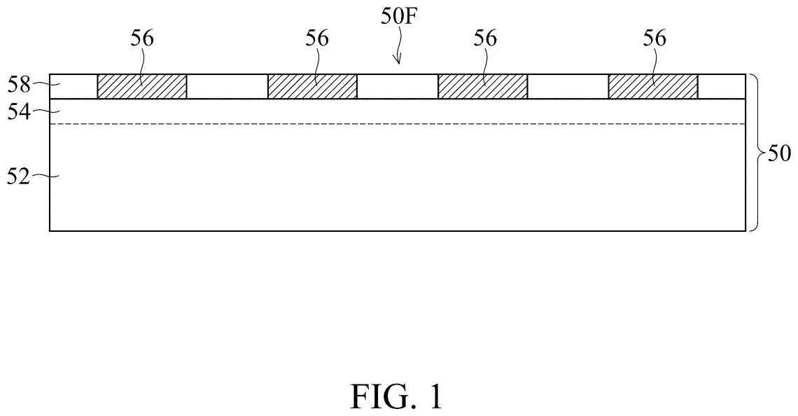

FIG. 1 is a cross-sectional view of an integrated circuit (IC) die 50. Multiple IC dies 50 will be packaged in subsequent processing to form an integrated circuit package. Each IC die 50 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). The IC die 50 may be formed in a wafer, which may include different die regions that are singulated in subsequent steps to form a plurality of IC dies 50. The IC die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (now shown for simplicity) are formed at the active surface of the semiconductor substrate 52. The devices may be active devices (e.g., transistors, diodes, etc.), capacitors, resistors, etc. The inactive surface may be free from devices.

The interconnect structure 54 is located over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobutene (BCB) based polymer, or the like. The metallization layers may include conductive vias and/or conductive lines to interconnect the devices on the semiconductor substrate 52. The metallization layers may be formed of a conductive material, such as a metal, such as copper, cobalt, aluminum, gold, combinations thereof, or the like. The interconnect structure 54 may be formed by a damascene process, such as a single damascene process, a dual damascene process, or the like.

Die connectors 56 are formed at the front-side 50F of the IC die 50. The die connectors 56 may be conductive pillars, pads, or the like, to which external connections are made. The die connectors 56 are located in and/or on the interconnect structure 54. For example, the die connectors 56 may be part of an upper metallization layer of the interconnect structure 54. The die connectors 56 can be formed of a metal, such as copper, aluminum, or the like, and can be formed by, for example, plating, or the like.

The dielectric layer 58 is formed at the front-side 50F of the IC die 50. The dielectric layer 58 is located in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a carbide, a polymer, the like, or a combination thereof. The dielectric layer 58 may be formed, for example, by spin coating, lamination, chemical vapor deposition (CVD), or the like. Initially, the dielectric layer 58 may bury the die connectors 56, so that the top surface of the dielectric layer 58 is above the top surfaces of the die connectors 56. The die connectors 56 are exposed through the dielectric layer 58 during formation of the IC die 50. A removal process may be performed on the dielectric layer 58 to expose the die connectors 56. The removal process may be a planarization process such as a chemical mechanical polish (CMP), an etch-back, combinations thereof, or the like. After the planarization process, top surfaces of the die connectors 56 and the dielectric layer 58 are substantially coplanar (within process variations). The die connectors 56 and the dielectric layer 58 are exposed at the front-side 50F of the IC die 50.

In some embodiments, the IC die 50 is a stacked device that includes multiple semiconductor substrates 52. For example, the IC die 50 may be a memory device that includes multiple memory dies such as a hybrid memory cube (HMC) device, a high bandwidth memory (HBM) device, or the like. In such embodiments, the IC die 50 includes multiple semiconductor substrates 52 interconnected by through-substrate vias (TSVs) such as through-silicon vias (not separately illustrated). Each of the semiconductor substrates 52 may (or may not) have a separate interconnect structure 54.

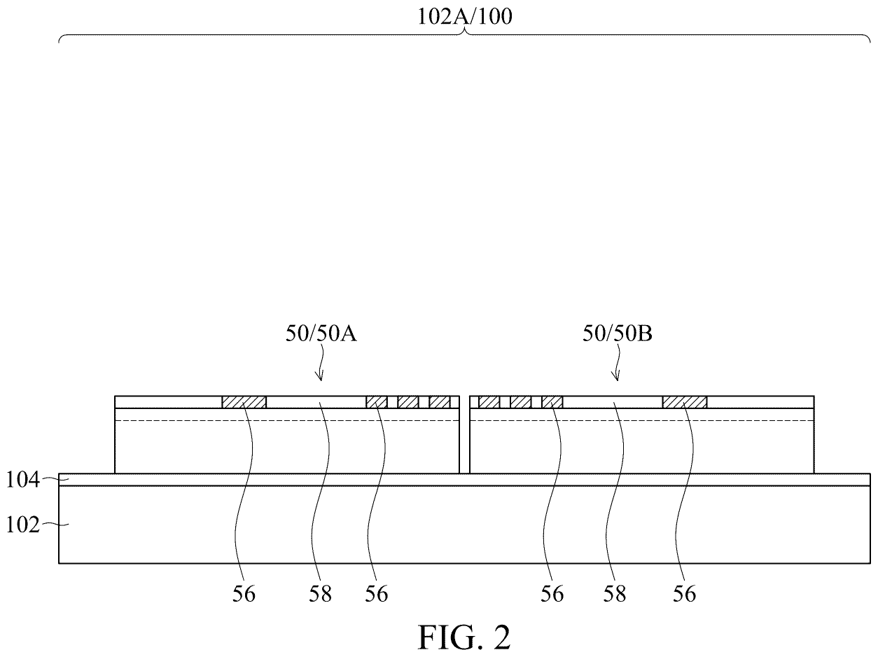

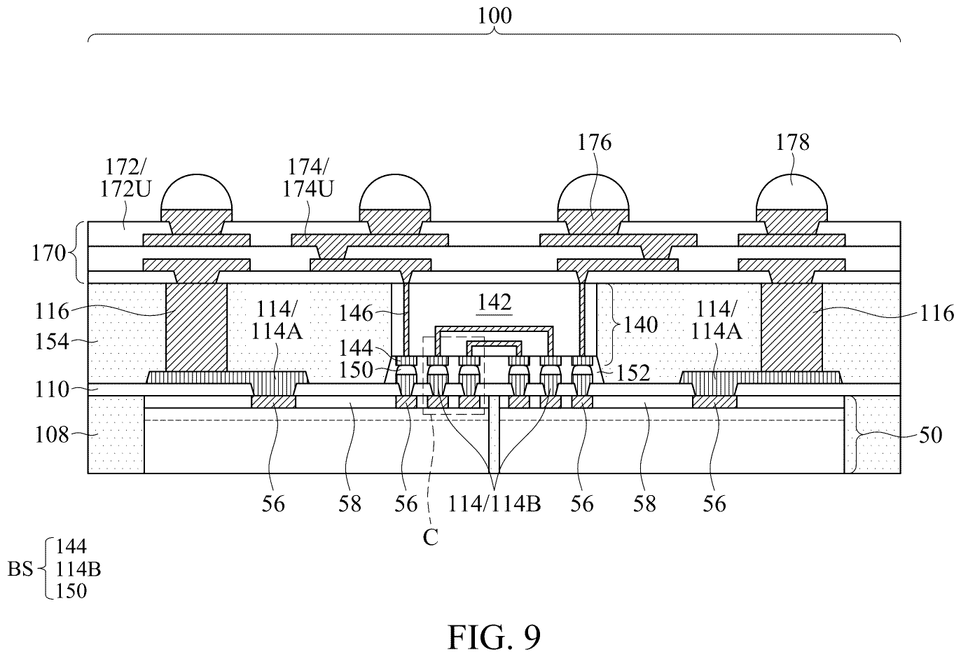

FIGS. 2 to 9 are cross-sectional views of intermediate stages in the formation of an integrated circuit package 100 (see FIG. 9), in accordance with some embodiments. Specifically, an integrated circuit package 100 is formed by packaging one or more IC dies 50 in a package region 102A. The package region 102A will be singulated in subsequent processing to form the integrated circuit package 100. Processing of one package region 102A is illustrated, but it should be appreciated that any number of package regions 102A can be simultaneously processed to form any number of integrated circuit packages 100. The completed integrated circuit package 100 may also be referred to as an integrated fan out (InFO) package.

In FIG. 2, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, so that multiple packages can be formed on the carrier substrate 102 simultaneously. The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and then subsequently cured, may be a laminate film laminated onto the carrier substrate 102, or may be the like.

Semiconductor dies such as IC dies 50 (e.g., a first IC die 50A and a second IC die 50B) are placed on the release layer 104. A desired type and quantity of IC dies 50 are placed in the package region 102A. The IC dies 50 may be placed by, e.g., a pick-and-place process. In the illustrated embodiment, multiple IC dies 50 are placed adjacent one another, including the first IC die 50A and the second IC die 50B in the package region 102A. The first IC die 50A may be a logic device, such as a central processing unit (CPU), graphics processing unit (GPU), system-on-a-chip (SoC), microcontroller, or the like. The second IC die 50B may be a memory device, such as a dynamic random access memory (DRAM) die, static random access memory (SRAM) die, hybrid memory cube (HMC) module, a high bandwidth memory (HBM) module, or the like. In some embodiments, the IC dies 50A, 50B may be the same type of dies, such as SoC dies. The first IC die 50A and the second IC die 50B may be formed in processes of the same technology node, or may be formed in processes of different technology nodes. For example, the first IC die 50A may be of a more advanced process node than the second IC die 50B. The IC dies 50A, 50B may have different sizes (e.g., different heights and/or surface areas), or may have the same size (e.g., same heights and/or surface areas).

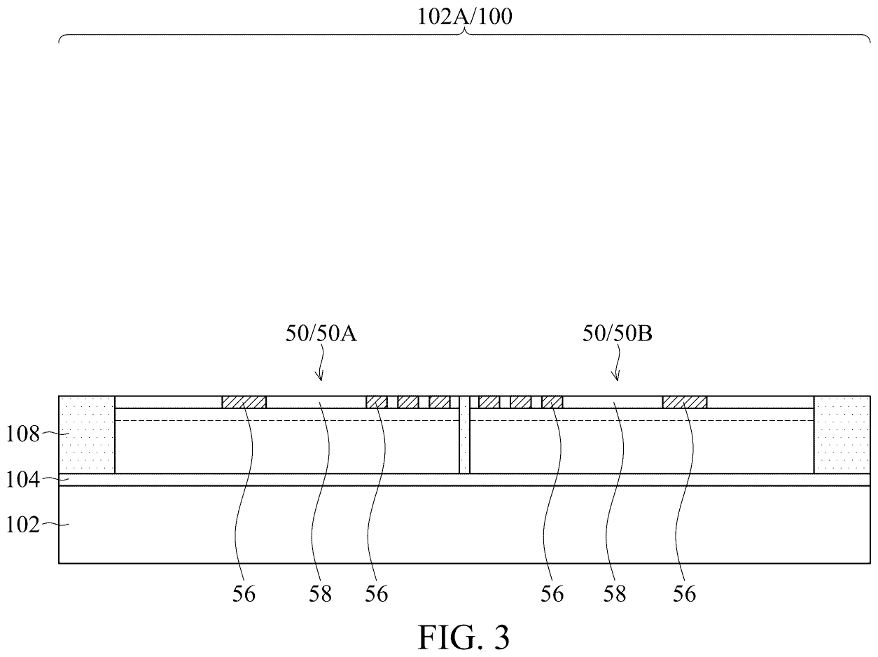

In FIG. 3, an encapsulant 108 is formed around the IC dies 50 and on the release layer 104. After formation, the encapsulant 108 encapsulates the IC dies 50. The encapsulant 108 may be a molding compound, epoxy, or the like. In some embodiments, the encapsulant 108 includes a polymer resin having fillers disposed therein. The encapsulant 108 may be applied by compression molding, transfer molding, or the like, and may be dispensed over the carrier substrate 102 so that the IC dies 50 are buried. The encapsulant 108 is further dispensed in gap regions between adjacent IC dies 50 in the package region 102A. The encapsulant 108 may be applied in liquid or semi-liquid form and then subsequently cured. A removal process may be performed on the encapsulant 108 to expose the die connectors 56 of the IC dies 50. The removal process may remove material of the encapsulant 108 and the IC dies 50 (e.g., the die connectors 56 and the dielectric layer 58) until the die connectors 56 are exposed. The removal process may be, for example, planarization process such as a chemical-mechanical polish (CMP), a grinding process, or the like. After the planarization process, top surfaces of the encapsulant 108 and the IC dies 50 (e.g., the die connectors 56 and the dielectric layer 58) are substantially coplanar (within process variations). In some embodiments, the removal process may be omitted, for example, if the die connectors 56 are already exposed.

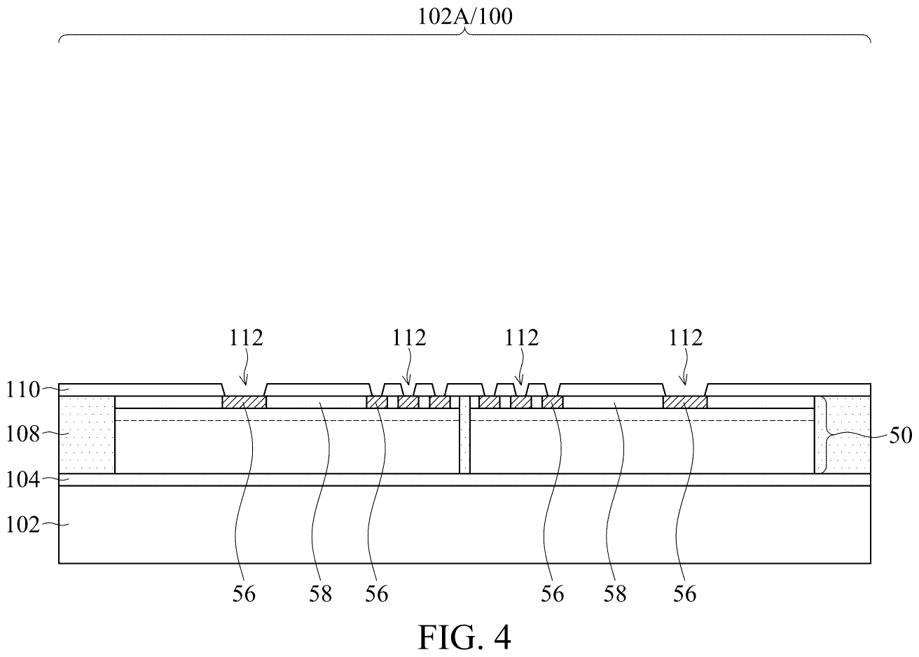

In FIG. 4, a dielectric layer 110 is deposited on the encapsulant 108 and the IC dies 50 (e.g., on the die connectors 56 and the dielectric layer 58). The dielectric layer 110 may be formed of a photosensitive material which may be patterned using a lithography mask, such as PBO, polyimide, a BCB-based polymer, a cyclic olefin copolymer, an acryl-based copolymer, or the like, which may be formed by spin coating, lamination, CVD, or the like. Other acceptable dielectric materials formed by any acceptable process may be used. The dielectric layer 110 is then patterned. The patterning forms openings 112 in the dielectric layer 110 exposing portions of the die connectors 56. The patterning may be performed by an acceptable process, such as by exposing the dielectric layer 110 to light and developing it when the dielectric layer 110 is a photosensitive material, or by etching using, for example, an anisotropic etch.

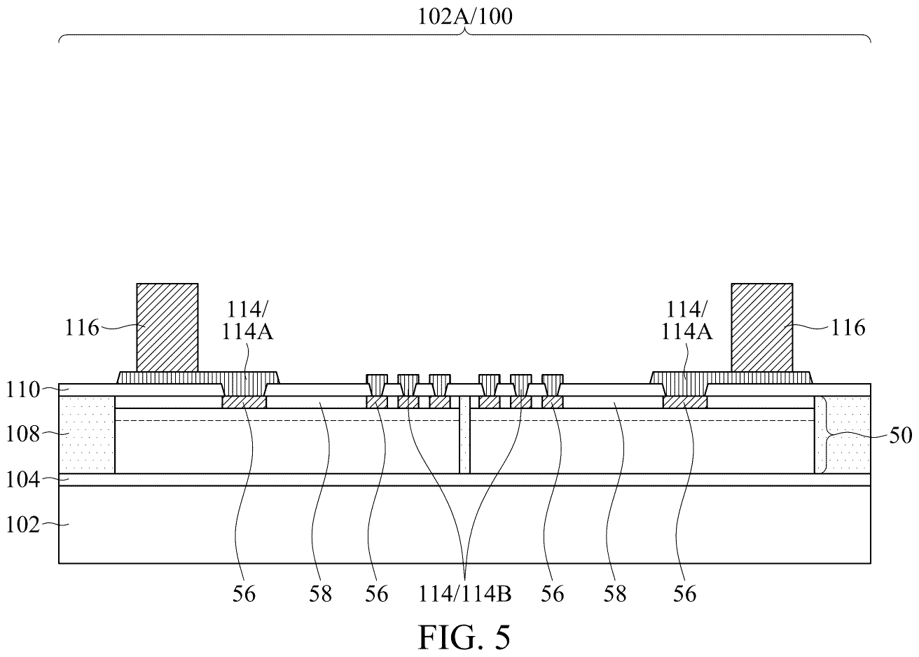

In FIG. 5, under-bump metallurgy layers (UBMLs) 114 are formed on the dielectric layer 110 and in the openings 112. The UBMLs 114 have line portions on and extending along the top surface of the dielectric layer 110, and have via portions extending through the dielectric layer 110 to contact the die connectors 56 of the IC dies 50, so that the UBMLs 114 are physically and electrically coupled to the IC dies 50.

As an example to form the UBMLs 114, a seed layer (not illustrated) is formed on the dielectric layer 110 and in the openings 112. In some embodiments, the seed layer is a metal layer, which may be a single layer or a composite layer comprising a plurality of sub-layers formed of different materials. In some embodiments, the seed layer includes a titanium layer and a copper layer over the titanium layer. The seed layer may be formed using, for example, physical vapor deposition (PVD) or the like. A lithography mask is then formed and patterned on the seed layer. The lithography mask may be a photoresist formed by spin coating or the like, and may be exposed to light for patterning. The pattern of the lithography mask corresponds to the UBMLs 114. The patterning forms openings through the lithography mask to expose the seed layer. A conductive material is then formed in the openings of the lithography mask and on the exposed portions of the seed layer. The conductive material may be a metal, such as copper, titanium, tungsten, aluminum, or the like, which may be formed by plating, such as electroless plating or electroplating, or the like. In some embodiment, the conductive material is a metal that is plated using the seed layer (e.g., through an electroplating process), which will be described in more detail below. After the conductive material is formed, the lithography mask is removed. In embodiments where the lithography mask is a photoresist, it may be removed by an acceptable ashing or stripping process, such as using an oxygen plasma or the like. After the lithography mask is removed, exposed portions of the seed layer may be removed, such as by using an acceptable etching process, such as by wet or dry etching. The remaining portions of the seed layer and the conductive material form the UBMLs 114.

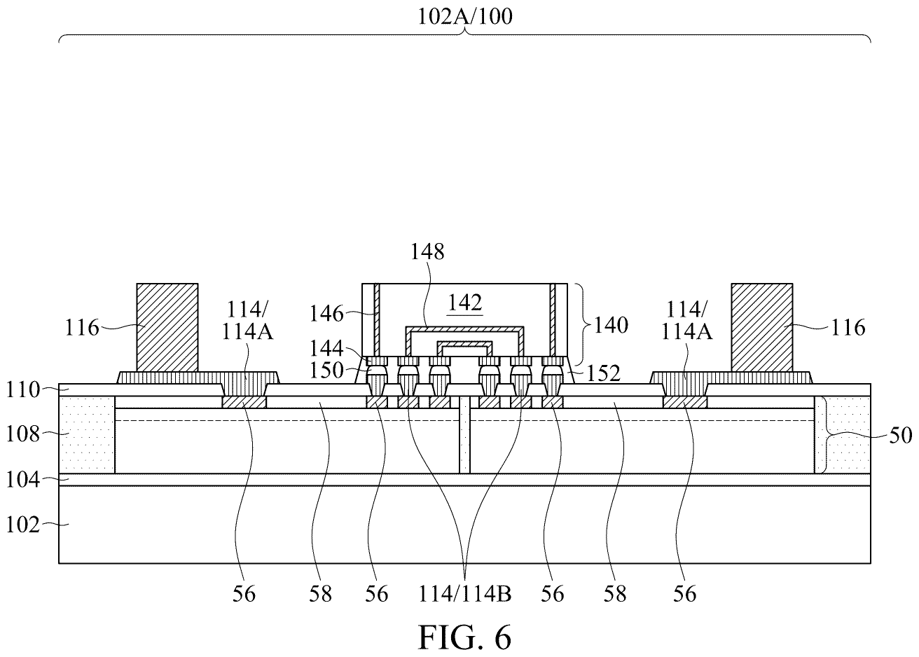

Through vias 116 are formed on a first subset of the UBMLs 114A (e.g., on the line portions of the UBMLs 114A). A second subset of the UBMLs 114B remain free of the through vias 116. The UBMLs 114A and the through vias 116 will be subsequently utilized for connection to higher layers of the integrated circuit package 100. The UBMLs 114B will be subsequently utilized for connection to interconnection dies 140 (e.g., see FIG. 6) that directly connect and allow communication between the IC dies 50 (e.g., between adjacent IC dies 50A and 50B in the package region 102A). The through vias 116 may be formed using materials and processes similar to those described above for the UBMLs 114. For example, the formation processes of the through vias 116 may include: forming a seed layer (not illustrated) on the UBMLs 114A (e.g., on the line portions of the UBMLs 114A); forming and patterning a lithography mask on the seed layer so that openings are formed through the lithography mask to expose portions of the seed layer; forming a conductive material in the openings of the lithography mask and on the exposed portions of the seed layer; and removing the lithography mask and exposed portions of the second seed layer on which the conductive material is not formed. The remaining portions of the second seed layer and the conductive material form the through vias 116. More details are not repeated here. In some embodiments, the materials used for the through vias 116 may be similar or the same as the materials used for the UBMLs 114.

In FIG. 6, one or more semiconductor dies, such as an interconnection die 140, are attached to the UBMLs 114B. The interconnection die 140 may be a local silicon interconnect (LSI) die, an interposer die, or the like. In the illustrated embodiment, one interconnection die 140 is attached to the UBMLs 114B in the package region 102A. It should be appreciated that any desired quantity of interconnection dies 140 may be placed in the package region 102A. The interconnection die 140 may be placed by, e.g., a pick-and-place process. The interconnection die 140 includes a substrate 142, with conductive features formed in and/or on the substrate 142. The substrate 142 may include a semiconductor substrate, one or more dielectric layer(s), or the like. The interconnection die 140 is attached to the UBMLs 114B using die connectors 144 (e.g., conductive pillars, pads, or the like) disposed at the front side of the interconnection die 140. Some of the die connectors 144 may be electrically coupled to the back side of the interconnection die 140 with through-substrate vias (TSVs) 146 that extend into or through the substrate 142. In the illustrated embodiment, the TSVs 146 extend through the substrate 142 so that they are exposed at the back sides of the interconnection die 140. In another embodiment, a material of the substrate 142 may cover the TSVs 146. In some embodiments, the die connectors 144 can be formed of a metal, such as copper, aluminum, or the like, and can be formed using processes similar to those described above for the UBMLs 114.

In embodiments where the interconnection die 140 is an LSI die, the interconnection die 140 may be a bridge structure that includes die bridges 148. The die bridges 148 may be metallization layers formed in and/or on the substrate 142, and work to interconnect each die connector 144 to another die connector 144. As such, the LSI can be used to directly connect and allow communication between the IC dies 50 (e.g., between adjacent IC dies 50A and 50B in the package region 102A). In such embodiments, the interconnection die 140 can be placed over a region that is disposed between the IC dies 50 so that each of the interconnection die 140 overlaps the underlying IC dies 50.

Conductive connectors 150 are formed on the UBMLs 114B and/or the die connectors 144. The conductive connectors 150 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 150 may include a conductive material such as solder, copper, aluminum, gold, nickel, silver, palladium, tin, the like, or a combination thereof. In some embodiments, the conductive connectors 150 are formed by initially forming a layer of solder through evaporation, electroplating, printing, solder transfer, ball placement, or the like. Once a layer of solder has been formed on the structure, a reflow may be performed in order to shape the material into the desired bump shapes. The interconnection die 140 is attached to the UBMLs 114B using the conductive connectors 150. Attaching the interconnection die 140 to the UBMLs 114B may include placing the interconnection die 140 on the UBMLs 114B and reflowing the conductive connectors 150 to physically and electrically couple the die connectors 144 to the UBMLs 114B.

In some embodiments, an underfill 152 is formed around the conductive connectors 150, and between the dielectric layer 110 and the interconnection die 140. The underfill 152 may reduce stress and protect the joints resulting from the reflowing of the conductive connectors 150. The underfill 152 may also be included to securely bond the interconnection die 140 to the dielectric layer 110 and provide structural support and environmental protection. The underfill 152 may be formed of a molding compound, epoxy, or the like. The underfill 152 may be formed by a capillary flow process after the interconnection die 140 is attached, or may be formed by a suitable deposition method before the interconnection die 140 is attached. The underfill 152 may be applied in liquid or semi-liquid form and then subsequently cured.

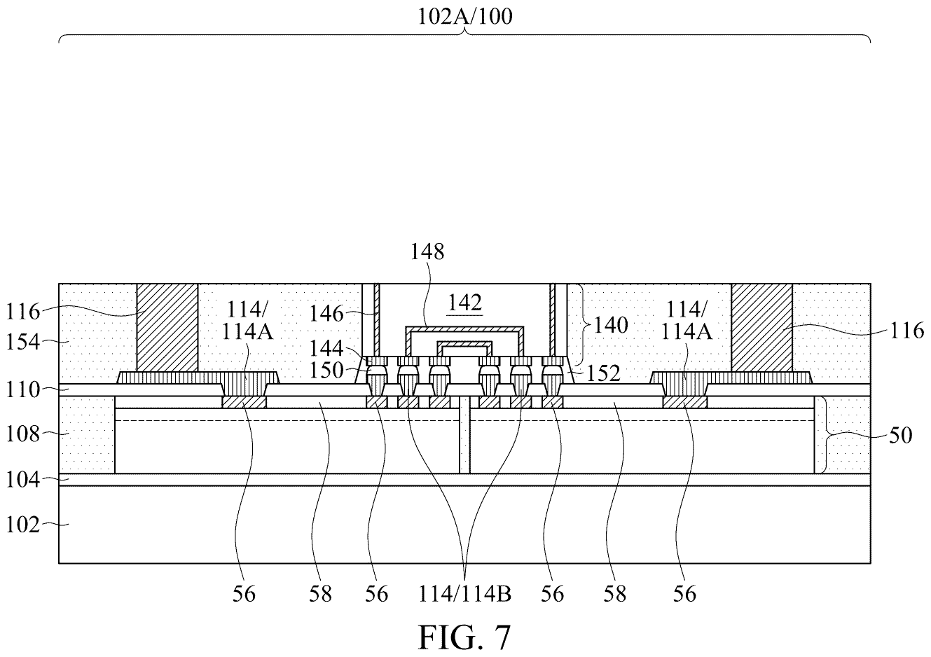

In FIG. 7, an encapsulant 154 is formed around the UBMLs 114, the through vias 116, the interconnection die 140, and the underfill 152 (if present) or the conductive connectors 150. After formation, the encapsulant 154 encapsulates the UBMLs 114, the through vias 116, the interconnection die 140, and the underfill 152 (if present) or the conductive connectors 150. The encapsulant 154 may be a molding compound, epoxy, or the like. The encapsulant 154 may be applied by compression molding, transfer molding, or the like, and may be dispensed on the dielectric layer 110, the UBMLs 114, the through vias 116, the interconnection die 140 so that the interconnection die 140 and the through vias 116 are buried or covered. The encapsulant 154 is further dispensed in gap regions between the interconnection die 140 and the through vias 116. The encapsulant 154 may be applied in liquid or semi-liquid form and then subsequently cured. A removal process may be performed on the encapsulant 154 to expose the TSVs 146 and the through vias 116. The removal process may remove material of the encapsulant 154, the interconnection die 140 (e.g., the TSVs 146 and the substrate 142), and the through vias 116 until the TSVs 146 and the through vias 116 are exposed. The removal process may be, for example, planarization process such as a chemical-mechanical polish (CMP), a grinding process, or the like. After the planarization process, top surfaces of the encapsulant 154, the interconnection die 140 (e.g., the TSVs 146 and the substrate 142), and the through vias 116 are substantially coplanar (within process variations). In some embodiments, the removal process may be omitted, for example, if the TSVs 146 and the through vias 116 are already exposed.

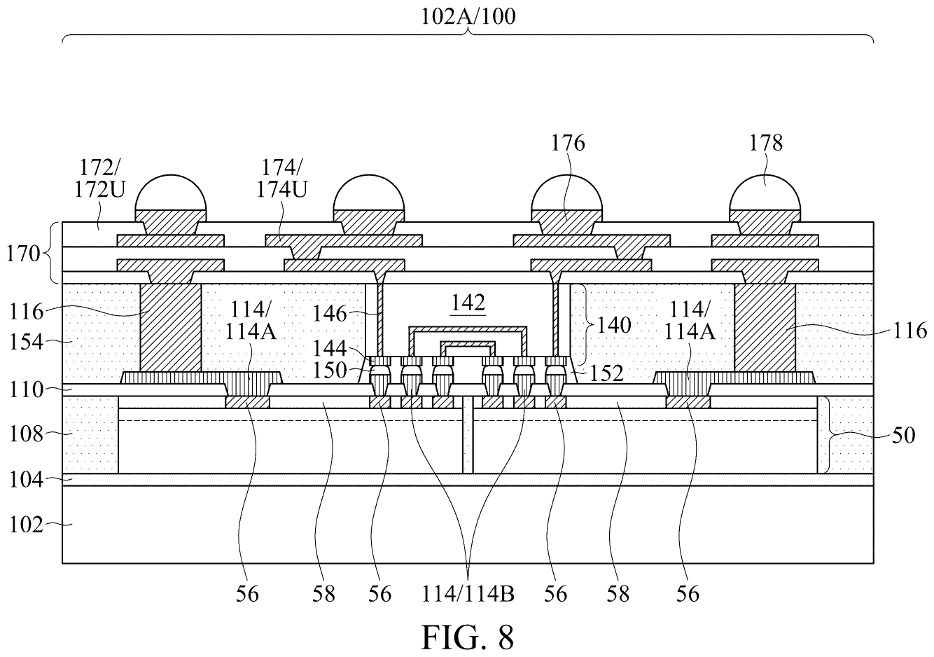

In FIG. 8, a redistribution structure 170 is formed on the top surfaces of the encapsulant 154, the interconnection die 140 (e.g., the TSVs 146 and the substrate 142), and the through vias 116. The redistribution structure 170 includes dielectric layers 172 and metallization layers 174 (sometimes referred to as redistribution layers or redistribution lines) formed in the dielectric layers 172. For example, the redistribution structure 170 may include a plurality of metallization layers 174 separated from each other by respective dielectric layers 172. The metallization layers 174 of the redistribution structure 170 are electrically coupled to the integrated circuit dies 50 by the through vias 116 and the interconnection die 140 (e.g., the TSVs 146).

In some embodiments, the dielectric layers 172 are formed of a polymer, which may be a photo-sensitive material such as PBO, polyimide, a BCB-based polymer, or the like. In other embodiments, the dielectric layers 172 are formed of a nitride such as silicon nitride; an oxide such as silicon oxide, PSG, BSG, BPSG; or the like. The dielectric layers 172 may be formed by spin coating, lamination, CVD, the like, or a combination thereof. After each dielectric layer 172 is formed, it is then patterned to form openings exposing underlying conductive features, such as portions of the underlying through vias 116, TSVs 146, or metallization layers 174. The patterning may be by an acceptable process, such as by exposing the dielectrics layers to light when the dielectric layers 172 are a photo-sensitive material, or by etching using, for example, an anisotropic etch. If the dielectric layers 172 are photo-sensitive materials, the dielectric layers 172 can be developed after the exposure.

The metallization layers 174 include conductive vias and conductive lines. The conductive vias extend through respective dielectric layers 172, and the conductive lines extend along respective dielectric layers 172. As an example to form a metallization layer 174, a seed layer (not illustrated) is formed over the respective underlying features. For example, the seed layer can be formed on a respective dielectric layer 172 and in the openings through the respective dielectric layer 172. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer. The patterning forms openings through the photoresist to expose the seed layer. A conductive material is then formed in the openings of the photoresist and on the exposed portions of the seed layer. The conductive material may be formed by plating, such as electroless plating or electroplating from the seed layer, or the like. The conductive material may comprise a metal or a metal alloy, such as copper, titanium, tungsten, aluminum, the like, or combinations thereof. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form a metallization layer 174 for one level of the redistribution structure 170.

The redistribution structure 170 is illustrated as an example. More or fewer dielectric layers 172 and metallization layers 174 than illustrated may be formed in the redistribution structure 170 by repeating or omitting the steps previously described.

Under-bump metallizations (UBMs) 176 are formed for external connection to the front-side redistribution structure 170. The UBMs 176 have bump portions on and extending along the top surface of the upper dielectric layer 172U of the redistribution structure 170, and have via portions extending through the upper dielectric layer 172U of the redistribution structure 170 to physically and electrically couple the upper metallization layer 174U of the redistribution structure 170. As a result, the UBMs 176 are electrically coupled to the through vias 116 and the interconnection die 140 (e.g., the TSVs 146). The UBMs 176 may be formed of the same material as the metallization layers 174, and may be formed by a similar process as the metallization layers 174. In some embodiments, the UBMs 176 have a different (e.g., larger) size than the metallization layers 174.

Conductive connectors 178 are formed on the UBMs 176. The conductive connectors 178 may be BGA connectors, solder balls, metal pillars, C4 bumps, micro bumps, ENEPIG formed bumps, or the like. The conductive connectors 178 may include a conductive material such as solder, copper, aluminum, gold, nickel, silver, palladium, tin, the like, or a combination thereof. In some embodiments, the conductive connectors 178 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 178 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In FIG. 9, a carrier substrate debonding process is performed to detach (or “debond”) the carrier substrate 102 from the integrated circuit dies 50 and the encapsulant 108. In some embodiments, the debonding process includes projecting a light such as a laser light or an UV light on the release layer 104 so that the release layer 104 decomposes under the heat of the light and the carrier substrate 102 can be removed.

Additional processing may be performed to complete formation of the integrated circuit package 100. For example, the package region 102A may be singulated to form the integrated circuit package 100. The singulation process may include sawing along scribe line regions (not illustrated), e.g., between the package region 102A and adjacent package regions. The sawing process singulates the package region 102A from the adjacent package regions, and the resulting integrated circuit package 100 is from the package region 102A.

As shown in FIG. 9, in the integrated circuit package 100, the interconnection die 140 is electrically coupled to the IC dies 50 (e.g., the die connectors 56) through the die connectors 144, conductive connectors 150, and the UBMLs 114B coupled to the die connectors 56. In the following description, each of the conductive connectors 150 (e.g., solder material) and a pair of corresponding die connector 144 and UBML 114B may be collectively referred to as a micro bump structure BS.

As mentioned above, solder joint necking is a common phenomenon caused by solder sidewall wetting during reflow (i.e., molten solder material 150 extends to the sidewalls of the die connector 144 of the interconnection die 140 and/or the UBML 114B above the IC die 50), which makes the micro bump structure weakened at this necking location and prone to cracking. The following describes some features of the micro bump structures BS that can overcome the above problems according to some embodiments of the present disclosure.

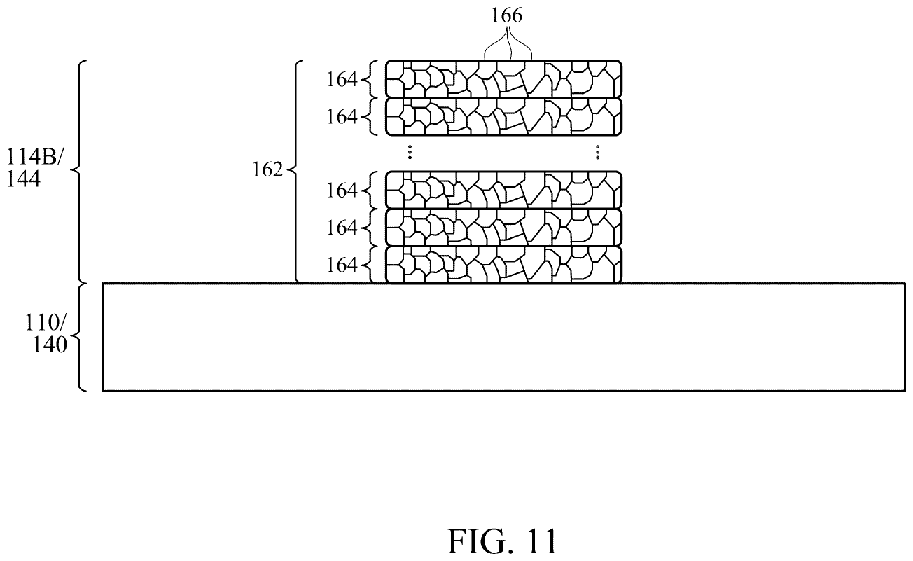

In some embodiments, the die connectors 144 of the interconnection die 140 and the UBMLs 114B above the IC die 50 are both formed of copper, so that the die connectors 144 and the UBMLs 114B are both copper layers. Each of the copper layers has polycrystalline structure including a plurality of grains. The grains have a uniform orientation, so that the majority of the grains have the same lattice direction. Forming the die connectors 144 and the UBMLs 114B from a copper layer with a uniform grain orientation (e.g., <111> orientation) allows molten solder material 150 to be confined on and between the top surfaces of the die connectors 144 and the UBMLs 114B without solder sidewall wetting occurring during reflow (i.e., molten solder material 150 will not extend to the sidewalls of the die connectors 144 and the UBMLs 114B), thereby preventing solder joint necking from occurring. The reason for this is that the top surface of a copper layer with a uniform grain orientation (e.g., <111> orientation) may have a lower surface energy (i.e., surface tension) than its sidewalls, so that molten solder material 150 has a smaller contact angle on the top surface and a larger contact angle on the sidewalls. Accordingly, the top surfaces of the die connector 144 and the UBML 114B are more easily wetted by molten solder material 150 than their corresponding sidewalls, which facilitates confining the molten solder material 150 to the top surfaces. The polycrystalline structure of the die connector 144 and UBML 114B will be subsequently described with reference to FIGS. 11 to 13. In other embodiments, the die connectors 144 and the UBMLs 114B may be formed of another conductive material (e.g., silver or gold) having a polycrystalline structure in which the majority of the grains have the same lattice direction (e.g., <111> or <211> orientation).

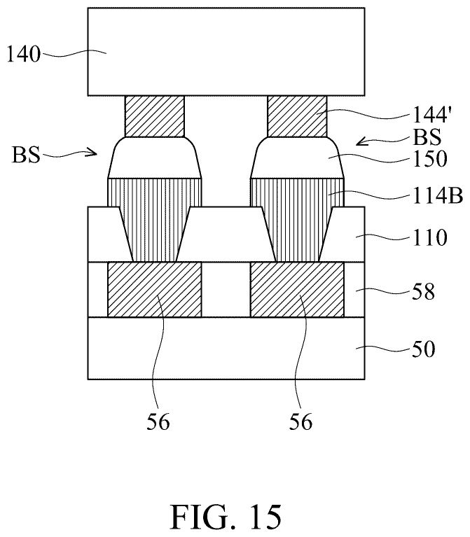

As an example to form a copper layer with a uniform grain orientation (for the die connectors 144 and the UBMLs 114B), a conductive material (e.g., copper) is plated on a seed layer (not separately illustrated). In some embodiments, the conductive material is formed by an electroplating process. Specifically, the conductive material is formed by submerging the seed layer in a plating solution. The plating solution may be, e.g., a sulfuric acid electrolyte containing some additives such as bis(3-sulfopropyl)disulfide, (SPS), polyethylene glycol (PEG), gelatin, sodium dodecyl sulfate (SDS) and the like. Another suitable plating solution and/or other suitable additives may be used. The plating solution includes cations of the conductive material. An electric current is applied to the plating solution to reduce the cations and thereby form the conductive material. The conductive material may be plated with a high plating current (which allows the electroplating process to form the conductive material with a uniform grain orientation) and may be plated for a suitable duration (depending on the desired thickness of the conductive material). In some embodiments, conductive material is plated with a plating current in the range of 7 A to 12 A and for a duration in the range of 250 seconds to 500 seconds, but embodiments of the present disclosure are not limited thereto. It should be appreciated that the copper layer with a uniform grain orientation is plated with a greater plating current than an ordinary copper layer with a non-uniform grain orientation or random lattice orientation. For example, an ordinary copper layer with non-uniform grain orientation (e.g., die connectors 144′ as shown in FIG. 15) may be plated with plating current in the range of 1 A to 5 A.

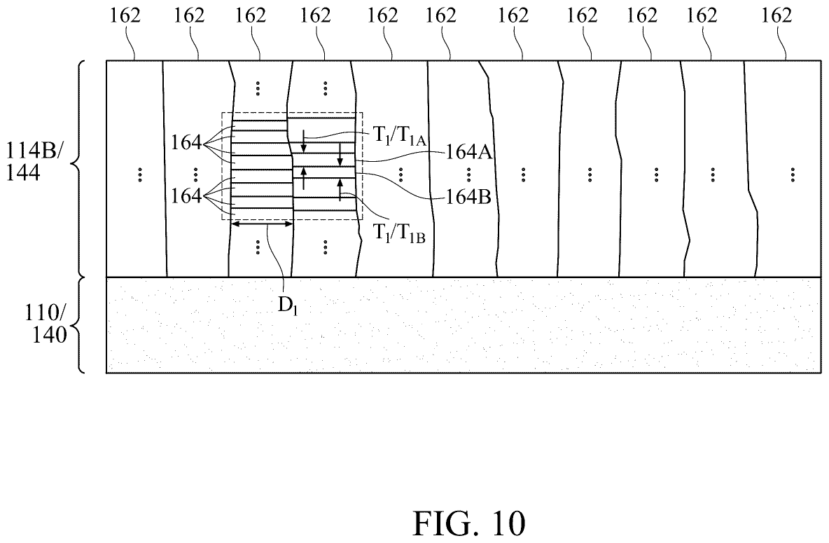

Next, the polycrystalline structure of the above die connector 144 and the UBML 114B are described with reference to FIGS. 10 to 12, which illustrate various views of the die connector 144 and the UBML 114B in accordance with some embodiments. For simplicity, in these figures, the die connector 144 and the UBML 114B are represented together by a single conductive material (e.g., copper) layer labeled 144/114B. For reference, the interconnection die 140/dielectric layer 110 adjacent to the bottom surface of the die connector 144/UBML 114B (e.g., the line portion of the UBML 114B) is also shown.

FIG. 10 illustrates a portion of the die connector 144/UBML 114B. The die connector 144/UBML 114B includes a plurality of nanocolumns 162 therein. The nanocolumns 162 have a lateral dimension D₁ (width or length). In some embodiments, the lateral dimension D₁ of a nanocolumn 162 is in the range of 200 nm to 2000 nm. The nanocolumns 162 are elongated in the vertical direction and form columns at the nanometer scale. The nanocolumns 162 have boundaries that are clear and distinguishable, for example, when viewed in X Ray Diffraction (XRD) images or Electron Back Scatter Diffraction (EBSD) images. Specifically, the nanocolumns 162 are separated from each other by vertical boundaries. The nanocolumns 162 may (or may not) extend from the bottom surface (the surface facing downward in FIG. 10) of the die connector 144/UBML 114B to the top surface (the surface facing upward in FIG. 10) of the die connector 144/UBML 114B. The edges of the nanocolumns 162 are substantially vertical, and may (or may not) be slightly curved or tilted, with the overall trend being away from the interconnection die 140 or dielectric layer 110.

FIG. 10 also illustrates details in some of the nanocolumns 162. The details of a middle portion of two nanocolumns 162 are shown. It should be appreciated that the other nanocolumns 162 may have similar structures as the illustrated nanocolumns 162. In accordance with some embodiments, each nanocolumn 162 includes a plurality of nanoplates 164 stacked up in the vertical direction to form the nanocolumn 162. The nanoplates 164 have interfaces that are clearly distinguishable, for example, when viewed in XRD images or EBSD images. The lateral dimensions D₁ of the nanoplates 164 are also the lateral dimension D₁ of the corresponding nanocolumns 162. The nanoplates 164 have a thickness T₁. In some embodiments, the thickness T₁ of a nanoplate 164 is in the range of 5 nm to 400 nm. In the cross-sectional view, the nanoplates 164 are elongated, with the lateral dimension D₁ of each nanoplate 164 being greater than its corresponding thicknesses T₁. In some embodiments, the ratio D₁/T₁ of a nanoplate 164 is in the range of 5 to 40. The thicknesses T₁ of different nanoplates 164 may be different from each other. In some embodiments, a ratio T_{1A}/T_{1B}, which is the thickness ratio of two neighboring nanoplates 164A, 164B, is in the range of 0.25 to 80. The thicknesses T₁ of different nanoplates 164 may be the same as each other, so that the ratio T_{1A}/T_{1B} is equal to 1.0. Further, the ratio of the greatest thickness of the nanoplates 164 to the smallest thickness of the nanoplates 164 in a nanocolumn 162 may be less than about 80. The top and bottom surfaces of nanoplates 164 in a nanocolumn 162 may be level with, higher than, or lower than (in a random way) the top and bottom surfaces of their contacting nanoplates 164 in neighboring nanocolumns 162.

In some embodiments, all of the nanocolumns 162 have clearly distinguishable edges (for example, in XRD images or EBSD images) contacting the edges of the neighboring nanocolumns 162. The edges are also substantially vertical. In other embodiments, most of the nanocolumns 162 have clearly distinguishable edges (which are substantially vertical) to separate them from the neighboring nanocolumns 162, while a small amount (for example, less than 5 percent, or even less than 1 percent) of nanoplates 164 may extend into neighboring nanocolumns 162. For example, some of the nanoplates 164 in two neighboring nanocolumns 162 may merge with each other so that no distinguishable edges separate them from each other.

FIG. 11 illustrates the polycrystalline structure of the die connector 144/UBML 114B. Specifically, the polycrystalline structure of a single nanocolumn 162 of the die connector 144/UBML 114B is shown. Other nanocolumns 162 are omitted for illustration clarity.

Each nanoplate 164 of the nanocolumns 162 has a polycrystalline structure including a plurality of grains 166 therein. Each of the grains 166 has a crystalline structure that is different from and/or misaligned from the crystalline structure of its neighboring grains 166 to form boundaries. The grains 166 inside each nanoplate 164 may have shapes different from each other and sizes different from each other. The boundaries of the grains 166 inside each nanoplate 164 are irregular (random without repeating patterns), and are not aligned to each other. The irregular pattern of the grains 166 in each nanoplate 164 is distributed throughout the nanoplate 164. The top surfaces of the top grains 166 inside each nanoplate 164 are substantially coplanar with each other to form a substantially planar top surface of the nanoplate 164, which also forms a planar interface with its overlying nanoplate 164. In some embodiments, the top surfaces of the top grains 166 of a nanoplate 164 have height variations smaller than about 5 percent of the thickness T₁. Similarly, the bottom surfaces of the bottom grains 166 inside each nanoplate 164 are substantially coplanar with each other to form a substantially planar bottom surface of the nanoplate 164. In some embodiments, the bottom surfaces of the bottom grains 166 of a nanoplate 164 have height variations smaller than about 5 percent of the thickness T₁. The edges of the grains 166 at a sidewall of a nanoplate 164 are also substantially aligned to form substantially vertical edges. In some embodiments, the offsets of the edges of the grains 166 at a sidewall of a nanoplate 164 are smaller than about 10 percent of the thickness T₁. Accordingly, in the cross-sectional view, each nanoplate 164 may have a rectangular shape with clearly distinguishable boundaries. The nanoplates 164 are separated from each other by horizontal boundaries.

The grains 166 of the nanoplates 164 have a uniform orientation. Specifically, the majority of the grains 166 of the nanoplates 164 may have the same lattice direction, which may be in <111> crystal plane. In some embodiments, more than 95 percent, or even up to 99 percent (by volume) of the grains 166 are <111> oriented, while the rest of the percent (by volume) of the grains 166 have other lattice orientations. In contrast, no majority of the grains of an ordinary copper layer have the same lattice direction. As described above, the polycrystalline structures of the die connector 144/UBML 114B may be formed by controlling parameters (e.g., the plating currents) of the plating processes used to form the conductive material.

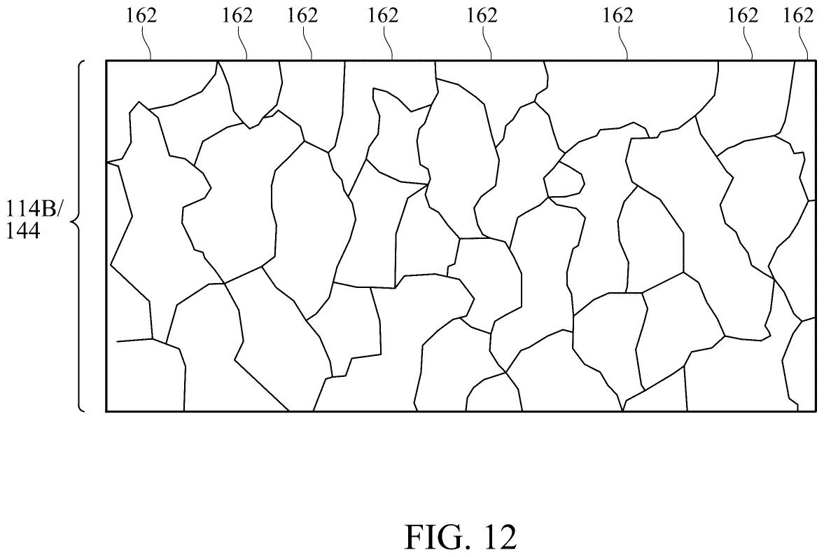

FIG. 12 is a top-down view of a portion of the die connector 144/UBML 114B. In the die connector 144/UBML 114B, a plurality of the nanocolumns 162 are arranged next to and joining with each other. The nanoplates 164 in the same nanocolumn 162 may have the same (or similar) shape and the same (or similar) size in the top-down view, which are also the shape and the size, respectively, in the top-down view of the respective nanocolumn 162 formed by these nanoplates 164.

As shown in FIGS. 10 to 12, a plurality of grains 166 collectively form the nanoplates 164, which have clear top surfaces, clear bottom surface, and clear edges, each of which are formed due to the alignment of the outer surfaces of the outer grains 166. A plurality of nanoplates 164 are stacked to form a nanocolumn 162. A plurality of nanocolumns 162 are further arranged to form a conductive material layer for the die connector 144/UBML 114B. In some embodiments, all of the nanocolumns 162 include nanoplates 164 therein. In other embodiments, some (for example, more than about 90 percent) of the nanocolumns 162 include nanoplates 164 therein, and those nanocolumns 162 may be referred to as stacked nano columns.

There may (or may not) be other nanocolumns 162 that do not have stacked nanoplates 164 therein, and those nanocolumns 162 may be referred to as non-stacked nanocolumns 162. The non-stacked nanocolumns 162 also have polycrystalline structures including a plurality of grains 166 therein, but do not have clear interfaces therein to divide the non-stacked nanocolumns 162 into stacked nano plates. Rather, the irregular pattern of grains 166 is distributed throughout the non-stacked nanocolumns 162. In some embodiments, the non-stacked nanocolumns 162 extend from the bottom surface of the die connector 144/UBML 114B to the top surface of the die connector 144/UBML 114B. An ordinary conductive material (e.g., copper) layer with a non-uniform grain orientation may have a similar structure as the non-stacked nanocolumns 162. In other embodiments, some of the nanocolumns 162 are divided into upper portions and lower portions, and the upper portions may be the non-stacked nanocolumns 162, while the corresponding lower portions are stacked nanocolumns 162, or vice versa.

As noted above, one of the advantages of using a conductive material layer with the above-mentioned highly textured structure as the die connector 144 and the UBML 114B is that the top surfaces of the layers of conductive material (i.e., the die connector 144 or the UBML 114B) have better wettability than the corresponding sidewalls, so that molten solder material 150 can be confined on and between the top surfaces of the die connectors 144 and the UBMLs 114B without solder sidewall wetting occurring during reflow. Therefore, the structural strength and reliability of the micro bump structures BS are improved. On the other hand, a conductive material layer with the above-mentioned highly textured structure also has better conductivity than an ordinary conductive material layer with a non-uniform grain orientation, so the electrical performance of the overall micro bump structure BS is also improved.

It should be noted that the term “highly textured structure” used herein may be understood as referring to a structure contains grains oriented in a particular direction. The highly textured structure may comprise or be composed of columnar grains. The columnar grain textured structure may include thermal conductive materials such as gold (Au), copper (Cu), or aluminum (Al), and may include metal grain with crystal orientation of a columnar structure. In particular, the term “highly textured structure” may refer to a structure in which an amount of columnar grain oriented in a particular direction (e.g., Cu <111> or columnar copper with <111> orientation) is greater than 75%, in some embodiments greater than 85%, and in another embodiment, greater than 95%. The highly textured structure may comprise twin boundaries, and a density of the twin boundaries among all crystal grain boundaries may be greater than 70% (e.g., >70%, >75%, >80%, >85%, >90%, or >95%).

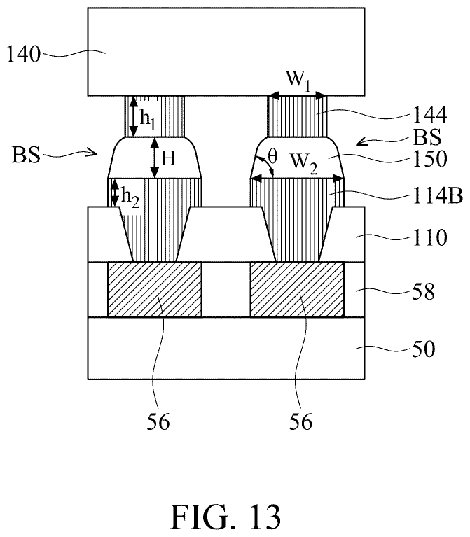

In some embodiments, the die connectors 144 and the UBMLs 114B may also be asymmetrical in lateral dimension. For example, referring to FIG. 13, which is an enlarged view of region C in FIG. 9, showing several micro bump structures BS between the interconnection die 140 and an IC die 50, in accordance with some embodiments. In the embodiment of FIG. 13, for each micro bump structure BS, the lateral dimension w₂ (e.g., width and/or length) of the UBML 114B (e.g., the line portion of the UBML 114B) may be larger than the lateral dimension w₁ (e.g., width and/or length) of the die connector 144. This helps to better confine (e.g., retain) the solder materials 150 to the top surfaces of the UBMLs 114B, as molten solder materials generally tends to flow the sidewalls of the underlying UBMLs 114B due to gravity. In some embodiments, the lateral dimension w₁ of the die connector 144 is in the range of 5 μm to 35 μm. The ratio w₁/w₂ is in the range of 0.2 to 0.8. Other lateral dimensions and other ratios may be used. Furthermore, by using the pair of die connector 144 and UBML 114B with asymmetric lateral dimensions, the solder material 150 confined therebetween may have an inverted bowl shape. In some embodiments, the contact angle θ between the solder material 150 and the top surface of the UBML 114B is in the range of 0 degrees to 90 degrees, and/or the vertical height H of the solder material 150 is in the range of 5 μm to 20 μm, depending on the amount of solder material 150 and the size of the ratio w₁/w₂.

Additionally or alternatively, in some embodiments, for each micro bump structure BS, the vertical height h₂ of the UBML 114B (e.g., the line portion of the UBML 114B) is less than the vertical height h₁ of the die connector 144. This helps reduce stress or torque generated during high temperature reflow process, for example, from being transmitted through the UBMLs 114B to the underlying IC die(s) 50, thereby preventing damage to the structures (e.g., low-k dielectric layers) in the IC die(s) 50. In some embodiments, the vertical height h₂ of the UBML 114B is in the range of 5 μm to 25 μm. The ratio h₂/h₁ is in the range of 0.2 to 0.8. Other lateral dimensions and other ratio values may be used. In other embodiments, the vertical height h₂ of the UBML 114B may be equal to the vertical height h₁ of the die connector 144 if there are no stress issues.

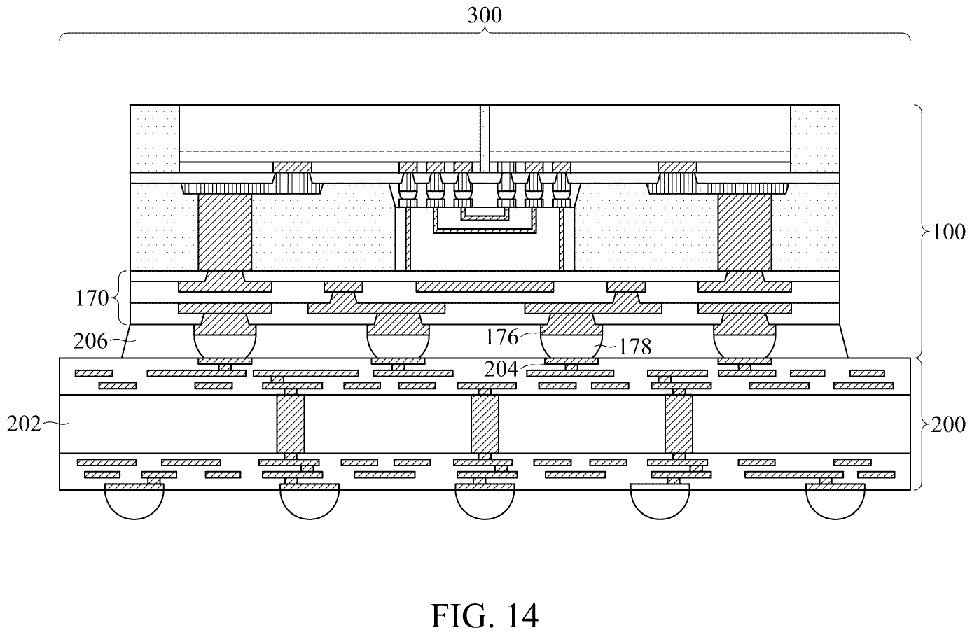

FIG. 14 is a cross-sectional view of an integrated circuit device 300, in accordance with some embodiments. The integrated circuit device 300 is formed by bonding an integrated circuit package 100 as described above to a package substrate 200. The bonding process may be, e.g., a flip-chip bonding process.

After the integrated circuit package 100 is formed, it is flipped and attached to a package substrate 200 using the conductive connectors 178. The package substrate 200 may be an interposer, a printed circuit board (PCB), or the like. The package substrate 200 includes a substrate core 202 and bond pads 204 over the substrate core 202. The substrate core 202 may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 202 may be a SOI substrate. Generally, an SOI substrate includes a layer of a semiconductor material such as epitaxial silicon, germanium, silicon germanium, SOI, SGOI, or combinations thereof. The substrate core 202 is, in one alternative embodiment, based on an insulating core such as a fiberglass reinforced resin core. One example core material is fiberglass resin such as FR4. Alternatives for the core material include bismaleimide-triazine (BT) resin, or alternatively, other PCB materials or films. Build up films such as Ajinomoto Build-up Film (ABF) or other laminates may be used for substrate core 202.

The substrate core 202 may include active and/or passive devices (not separately illustrated). A wide variety of devices such as transistors, capacitors, resistors, combinations of these, and the like may be used to generate the structural and functional designs for the device stack. The devices may be formed using any suitable methods.

The substrate core 202 may also include metallization layers and vias, with the bond pads 204 being physically and/or electrically coupled to the metallization layers and vias. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some embodiments, the substrate core 202 is substantially free of active and passive devices.

In some embodiments, the conductive connectors 178 are reflowed to attach the UBMs 176 to the bond pads 204. The conductive connectors 178 physically and/or electrically couple the package substrate 200, including metallization layers in the substrate core 202, to the integrated circuit package 100, including metallization layers in the redistribution structure 170. In some embodiments, a solder resist (not separately illustrated) is formed on the substrate core 202. The conductive connectors 178 may be disposed in openings in the solder resist to be physically and electrically coupled to the bond pads 204. The solder resist may be used to protect areas of the package substrate 200 from external damage.

An underfill 206 may be formed between the integrated circuit package 100 and the package substrate 200, surrounding the conductive connectors 178 to reduce stress and protect the joints resulting from the reflowing the conductive connectors 178. In some embodiments, the underfill 206 is formed by a capillary flow process after the integrated circuit package 100 is attached or is formed by a suitable deposition method before the integrated circuit package 100 is attached.

In some embodiments, passive devices (e.g., surface mount devices (SMDs), not separately illustrated) may also be attached to the integrated circuit package 100 (e.g., to the UBMs 176) or to the package substrate 200 (e.g., to the bond pads 204). For example, the passive devices may be bonded to the same surface of the integrated circuit package 100 or the package substrate 200 as the conductive connectors 178. The passive devices may be attached to the integrated circuit package 100 prior to mounting the integrated circuit package 100 to the package substrate 200, or may be attached to the package substrate 200 after mounting the integrated circuit package 100 to the package substrate 200. In some embodiments, additional integrated circuit dies (not separately illustrated) similar to the IC dies 50 may also be attached to the package substrate 200 (e.g., to the bond pads 204) to generate the desired functional design of the integrated circuit device 300.

In some embodiments, a metal lid (not separately illustrated) is attached to the package substrate 200 through adhesive, which helps reduce warpage of the package substrate 200. In some embodiments, the metal lid is also attached to the top surface of the integrated circuit package 100 through a thermal interface material (TIM) to help dissipate heat. In other embodiments, the metal lid may be replaced by a stiffener ring.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Many variations and/or modifications can be made to embodiments of the disclosure. For example, the aforementioned micro bump structures BS for the interconnection die 140 can have some variations. Some variations of some embodiments are described below with reference to FIGS. 15 to 20.

In the embodiment of FIG. 15, the micro bump structures BS are similar to the micro bump structures BS previously described in FIGS. 9 and 13, except that the die connectors 144 of the interconnection die 140 are replaced by die connectors 144′ formed from an ordinary copper layer with a non-uniform grain orientation. The UBMLs 114B are still formed from a copper layer with a uniform grain orientation (e.g., <111> orientation). It should be appreciated that molten solder materials 150 are susceptible to gravity and flows to the sidewalls of the underlying UBMLs 114B (and less likely to flow to the sidewalls of the overlying die connectors 144′ of the interconnection die 140), so the micro bump structures BS including only the underlying UBMLs 114B with a uniform grain oriented copper layer may still help to confine the solder materials 150 on and between the top surfaces of the die connectors 144′ and the UBMLs 114B without solder sidewall wetting occurring during reflow.

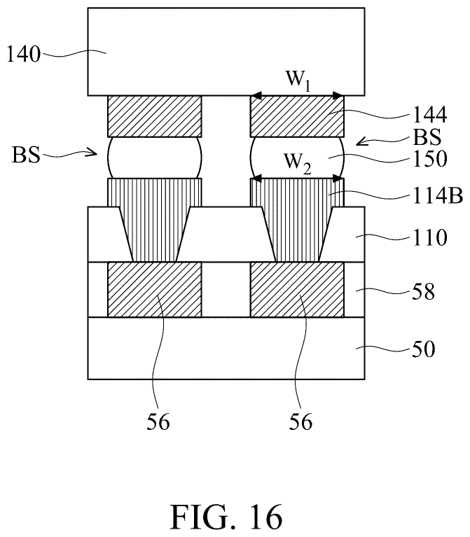

In the embodiment of FIG. 16, the micro bump structures BS are similar to the micro bump structures BS previously described in FIGS. 9 and 13, except that the die connectors 144 and the UBMLs 114B are symmetrical in lateral dimension. For example, for each micro bump structure BS, the lateral dimension w₂ (e.g., width and/or length) of the UBML 114B (e.g., the line portion of the UBML 114B) is substantially equal to the lateral dimension w₁ (e.g., width and/or length) of the die connector 144 (within process variations). Such micro bump structures BS can still confine the solder materials 150 on and between the top surfaces of the die connectors 144 and the UBMLs 114B without solder sidewall wetting occurring during reflow, as long as the amount of solder material is appropriate.

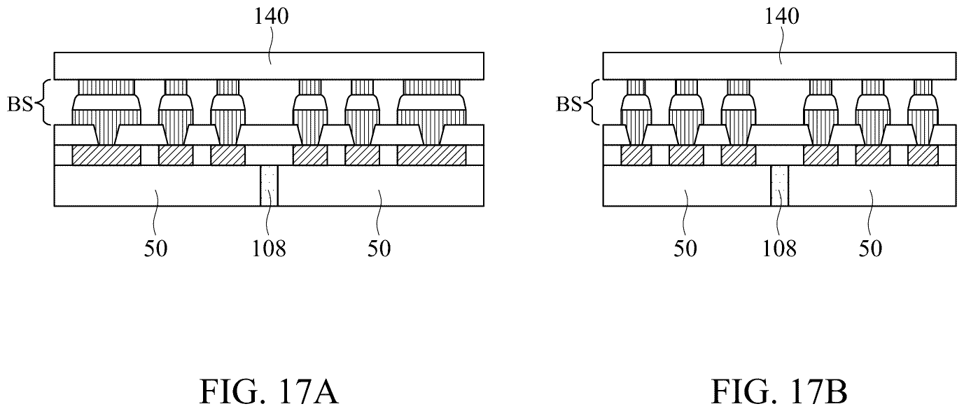

In the embodiments of FIGS. 17A and 17B, the micro bump structures BS in the peripheral region of the interconnection die 140 may have different (e.g., larger or smaller) size (e.g., lateral cross-sectional area) than the micro bump structures BS in the central region of the interconnection die 140. This helps the interconnection dies 140 with different warpage patterns (e.g., caused by different CTEs of various components) to successfully attach to the IC dies 50 through these micro bump structures BS. For example, in embodiments where the interconnection die 140 is bent into a smiley face (i.e., the edges warp upward), the micro bump structures BS in the peripheral region of the interconnection die 140 may have a larger size (e.g., lateral cross-sectional area) than the micro bump structures BS in the central region of the interconnection die 140 to allow the edges of the interconnection die 140 to be better attached to the IC dies 50, as shown in FIG. 17A. In embodiments where the interconnection die 140 is bent into a crying face (i.e., the edges warp downward), the micro bump structures BS in the peripheral region of the interconnection die 140 may have a smaller size (e.g., lateral cross-sectional area) than the micro bump structures BS in the central region of the interconnection die 140 to allow the edges of the interconnection die 140 to be better attached to the IC dies 50, as shown in FIG. 17B.

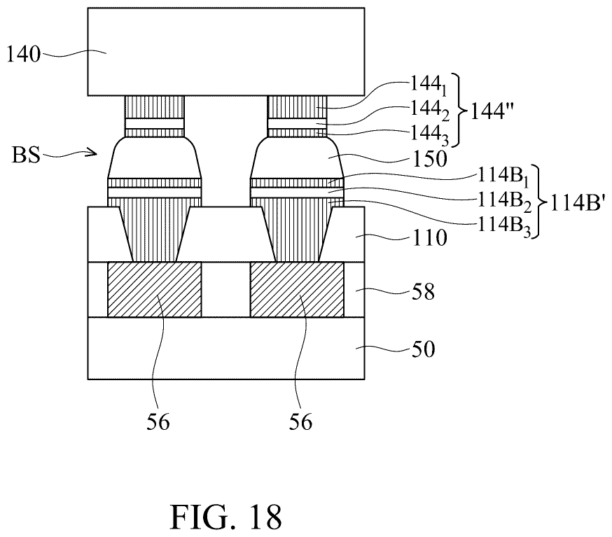

In the embodiment of FIG. 18, both the die connectors 144 and the UBMLs 114B include multilayered structures. For example, each of the die connectors 144 includes a bottom layer 144₁, an intermediate layer 144₂ on the bottom layer 144₁, and a top layer 144₃ on the intermediate layer 144₂. In some embodiments, both the bottom layer 144₁ and the top layer 144₃ of a die connector 144 are uniform grain oriented copper layers, and the intermediate layer 144₂ serves as a diffusion barrier and may include nickel. Similarly, each of the UBMLs 114B includes a bottom layer 114B₁, an intermediate layer 114B₂ on the bottom layer 114B₁, and a top layer 114B₃ on the intermediate layer 114B₂. In some embodiments, both the bottom layer 114B₁ and the top layer 114B₃ of an UBML 114B are uniform grain oriented copper layers, and the intermediate layer 114B₂ serves as a diffusion barrier and may include nickel. With the top layers 144₃, 114B₃ of the die connectors 144, UBMLs 114B being uniform grain oriented (e.g., <111> orientation) copper layers, the solder materials 150 may also be confined on and between the top surfaces of the die connectors 144 and the UBMLs 114B without solder sidewall wetting occurring during reflow, similar to the embodiments of FIGS. 9 and 13. In other embodiments, the die connectors 144 and the UBMLs 114B may include multilayered structures with different material compositions, as long as the top layers of the die connectors 144 and the UBMLs 114B are uniform grain oriented copper layers that facilitate constrained flow of the solder materials 150.

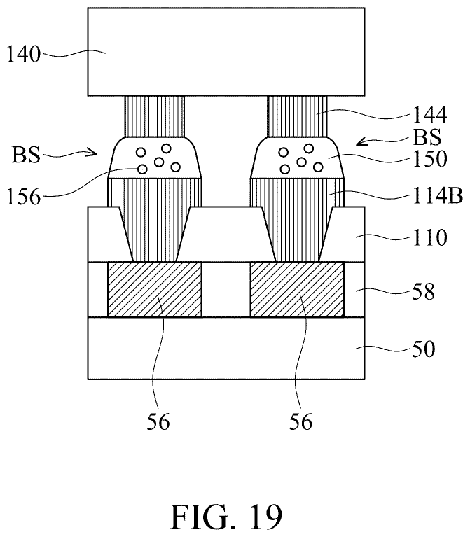

In the embodiment of FIG. 19, the micro bump structures BS are similar to the micro bump structures BS previously described in FIGS. 9 and 13, except that conductive beads 156 (e.g., copper beads 156) are added to the solder materials 150. Adding copper beads 156 to the solder materials 150 helps improve the conductivity of the micro bump structures BS. In some embodiments, the copper beads 156 have a size (e.g., diameter) in the range of 0.01 μm to 2 μm. In some embodiments, the ratio of the volume of the copper beads 156 to the volume of the corresponding solder material 150 is in the range of 5 percent to 30 percent. Other sizes or other ratios may be used.

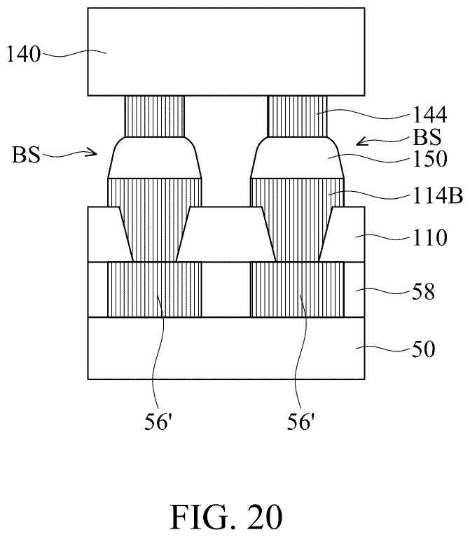

In the embodiment of FIG. 20, the micro bump structures BS are the same as the micro bump structures BS previously described in FIGS. 9 and 13, but the die connectors 56 of the IC dies 50 are replaced by die connectors 56′ formed from a copper layer with a uniform grain orientation (e.g., <111> orientation). This helps improve the electrical performance of the overall package structure (e.g., integrated circuit package 100) because a copper layer with a uniform grain orientation has better conductivity than an ordinary copper layer with a non-uniform grain orientation.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure. For example, various features in the above-mentioned different embodiments can be combined arbitrarily.

In summary, the embodiments of the present disclosure have some advantageous features. By forming the UBMLs overlying the IC dies and the die connectors of the interconnection die with layers of conductive material (e.g., copper, silver or gold) with uniform grain orientation (e.g., <111> or <211> orientation), it allows for the top surfaces of the UBMLs and the die connectors have better wettability than the corresponding sidewalls so that molten solder material 150 can be confined on and between the top surfaces of the die connectors 144 and the UBMLs 114B without solder sidewall wetting occurring during reflow (i.e., avoid solder joint necking). Accordingly, the structural strength and reliability of the micro bump structures for the interconnection die are improved. Furthermore, the electrical performance (e.g., conductivity) of the micro bump structures are also improved.

In accordance with some embodiments, a semiconductor device is provided. The semiconductor device includes an integrated circuit die, a dielectric layer, an under-bump metallurgy layer, an interconnection die, and a solder material. The integrated circuit die includes a first die connector. The dielectric layer is located on the integrated circuit die. The under-bump metallurgy layer has a line portion on the dielectric layer and a via portion extending through the dielectric layer to contact the first die connector. The interconnection die includes a second die connector. The solder material is located between the line portion of the under-bump metallurgy layer and the second die connector. The under-bump metallurgy layer includes a first conductive material layer having a uniform grain orientation, wherein the top surface of the first conductive material layer is in direct contact with the solder material.

In accordance with some embodiments, a semiconductor device is provided. The semiconductor device includes a first integrated circuit die and a second integrated circuit die, a dielectric layer, a plurality of under-bump metallurgy layers, an interconnection die, and a plurality of solder materials. The first integrated circuit die and the second integrated circuit die are adjacent to each other and include a plurality of first die connectors. The dielectric layer is located on the first integrated circuit die and the second integrated circuit die. Each of the under-bump metallurgy layers have a line portion on the dielectric layer and a via portion extending through the dielectric layer to contact one of the first die connectors. The interconnection die includes a plurality of second die connectors and a die bridge. The die bridge interconnects one of the second die connectors to another of the second die connectors. The solder materials are located between and in direct contact with the line portions of the under-bump metallurgy layers and the second die connectors. Each of the under-bump metallurgy layers includes a plurality of first metal grains, the majority of the first metal grains having the same lattice direction.

In accordance with some embodiments, a method of forming a semiconductor device is provided. The method includes forming a dielectric layer on an integrated circuit die, the dielectric layer having an opening that exposes a first die connector of the integrated circuit die. The method includes forming an under-bump metallurgy layer on the dielectric layer and in the opening, the under-bump metallurgy layer including a line portion on the dielectric layer and a via portion extending through the dielectric layer to contact the first die connector. The method includes attaching an interconnection die including a second die connector to the line portion of the under-bump metallurgy layer through a solder material between the second die connector and the line portion. The method includes reflowing the solder material to physically and electrically couple the second die connector to the line portion of the under-bump metallurgy layer. The under-bump metallurgy layer includes a first copper layer having a uniform grain orientation so that the top surface of the line portion of the under-bump metallurgy layer has better wettability than the sidewalls of the line portion. The second die connector includes a second copper layer having a uniform grain orientation so that the top surface of the second die connector has better wettability than the sidewalls of the second die connector.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an integrated circuit die comprising a first die connector;
a dielectric layer on the integrated circuit die;
an under-bump metallurgy layer having a line portion on the dielectric layer and a via portion extending through the dielectric layer to contact the first die connector;
an interconnection die comprising a second die connector; and
a solder material between the line portion of the under-bump metallurgy layer and the second die connector,
wherein the under-bump metallurgy layer comprises a first conductive material layer having a uniform grain orientation, and a top surface of the first conductive material layer is in direct contact with the solder material.

2. The semiconductor device as claimed in claim 1, wherein the first conductive material has <111> or <211> grain orientation.

3. The semiconductor device as claimed in claim 1, wherein the first conductive material is metal and comprises copper, silver or gold.

4. The semiconductor device as claimed in claim 3, wherein the first conductive layer comprises a plurality of metal nanocolumns, each of the metal nanocolumns comprises a plurality of metal nanoplates, and the metal nanoplates are stacked in a vertical direction extending away from the dielectric layer.

5. The semiconductor device as claimed in claim 4, wherein the metal nanocolumns are separated from each other by vertical boundaries, and the metal nanoplates are separated from each other by horizontal boundaries.

6. The semiconductor device as claimed in claim 1, wherein an amount of the first conductive material in the under-bump metallurgy layer is greater than 75%.

7. The semiconductor device as claimed in claim 1, wherein the second die connector of the interconnection die comprises a second conductive material layer having a uniform grain orientation, and a top surface of the second conductive material layer is in direct contact with the solder material.

8. The semiconductor device as claimed in claim 1, wherein a lateral dimension of the line portion of the under-bump metallurgy layer is larger than a lateral dimension of the second die connector.

9. The semiconductor device as claimed in claim 1, wherein a vertical height of the line portion of the under-bump metallurgy layer is less than a vertical height of the second die connector.

10. The semiconductor device as claimed in claim 1, wherein the under-bump metallurgy layer comprises a multilayered structure, the multilayered structure has a top layer, and the first conductive material layer is the top layer of the multilayered structure.

11. A semiconductor device, comprising:
a first integrated circuit die and a second integrated circuit die adjacent to the first integrated circuit die, wherein the first integrated circuit die and the second integrated circuit die comprise a plurality of first die connectors;
a dielectric layer on the first integrated circuit die and the second integrated circuit die;
a plurality of under-bump metallurgy layers, wherein each of the under-bump metallurgy layers has a line portion on the dielectric layer and a via portion extending through the dielectric layer to contact one of the first die connectors;
an interconnection die comprising a plurality of second die connectors and a die bridge, wherein the die bridge connects one of the second die connectors to another of the second die connectors; and
a plurality of solder materials between and in direct contact with the line portions of the under-bump metallurgy layers and the second die connectors,
wherein each of the under-bump metallurgy layers comprises a plurality of first metal grains, and a majority of the first metal grains have a same lattice direction.

12. The semiconductor device as claimed in claim 11, wherein the majority of the first metal grains are <111> oriented, and
wherein an amount of the first metal grains having the same lattice direction in the under-bump metallurgy layer is greater than 75%.

13. The semiconductor device as claimed in claim 11, wherein each of the second die connectors comprises a plurality of second metal grains, a majority of the second metal grains have a same lattice direction, and the majority of the second metal grains are <111> oriented.

14. The semiconductor device as claimed in claim 11, wherein:
one of the under-bump metallurgy layers located in a peripheral region of the interconnection die has a larger lateral size than one of the under-bump metallurgy layers located in a central region of the interconnection die;
one of the second die connectors located in the peripheral region of the interconnection die has a larger lateral size than one of the second die connectors located in the central region of the interconnection die; and
one of the solder materials located in the peripheral region of the interconnection die has a larger lateral size than one of the solder materials located in the central region of the interconnection die.

15. The semiconductor device as claimed in claim 11, wherein:
one of the under-bump metallurgy layers located in a peripheral region of the interconnection die has a smaller lateral size than one of the under-bump metallurgy layers located in a central region of the interconnection die;
one of the second die connectors located in the peripheral region of the interconnection die has a smaller lateral size than one of the second die connectors located in the central region of the interconnection die; and
one of the solder materials located in the peripheral region of the interconnection die has a smaller lateral size than one of the solder materials located in the central region of the interconnection die.

16. The semiconductor device as claimed in claim 11, further comprising:
a plurality of through vias on the line portions of some of the under-bump metallurgy layers;
an encapsulant around the through vias, the under-bump metallurgy layers, and the interconnection die; and
a redistribution structure on the encapsulant, wherein the redistribution structure comprises a redistribution line, and the redistribution line is physically and electrically coupled to the through vias.

17. The semiconductor device as claimed in claim 11, wherein the interconnection die is a local silicon interconnect die.

18. A method of forming a semiconductor die, comprising:
forming a dielectric layer on an integrated circuit die, wherein the dielectric layer has an opening exposing a first die connector of the integrated circuit die;
forming an under-bump metallurgy layer on the dielectric layer and in the opening, wherein the under-bump metallurgy layer comprises a line portion on the dielectric layer and a via portion extending through the dielectric layer to contact the first die connector;
attaching an interconnection die comprising a second die connector to the line portion of the under-bump metallurgy layer through a solder material between the second die connector and the line portion; and
reflowing the solder material to physically and electrically couple the second die connector to the line portion of the under-bump metallurgy layer,
wherein the under-bump metallurgy layer comprises a first copper layer having a uniform grain orientation so that a top surface of the line portion of the under-bump metallurgy layer has better wettability than sidewalls of the line portion, and
wherein the second die connector comprises a second copper layer having a uniform grain orientation so that a top surface of the second die connector has better wettability than sidewalls of the second die connector.

19. The method as claimed in claim 18, wherein an entirety of the solder material is confined on and between the top surfaces of the line portion of the under-bump metallurgy layer and the second die connector and does not contact sidewalls of the line portion of the under-bump metallurgy layer and the second die connector.

20. The method as claimed in claim 18, wherein:
the first copper layer comprises a plurality of first copper grains, and a majority of the first copper grains are <111> oriented; and
the second copper layer comprises a plurality of second copper grains, and a majority of the second copper grains are <111> oriented.
